(19) United States
(12) Patent Application Publication
(10) Pub. No.: US 2005/0145866 A1
(43) Pub. Date: Jul. 7, 2005

(54) Method and apparatus for forming thin film of organic electroluminescent device

(76) Inventors: Yu-San Lee, Hsinchu County (TW); Chien-Lang Chen, Tainan City (TW); Chun-Chien Chen, Hsinchu County (TW); Lai-Cheng Chen, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,785

(22) Filed: Aug. 3, 2004

(30) Foreign Application Priority Data
Jan. 6, 2004 (TW) 93100200

(51) Int. Cl. H01L 21/00; H01L 29/08; H01L 35/24; H01L 51/00; H01L 33/00; G10H 3/00

(52) U.S. Cl. 257/98; 438/29; 438/99; 257/40

(57) ABSTRACT

A method for forming a thin film layer of an organic electroluminescent device is disclosed. The method is adapted to form a patterned film on a substrate. The method first provides a mask. Then, an alignment process is performed to align the substrate and the mask under non-vacuum environment, and the substrate and the mask are fastened. The substrate and the mask are transferred in vacuum environment so that the patterned film can be formed on the substrate. In the method mentioned above, the throughput thereof will be improved.

### CROSS REFERENCE TO RELATED APPLICATIONS

This application claims the priority benefit of Taiwan application serial no. 93100200, filed Jan. 6, 2004.

### BACKGROUND OF INVENTION

1. Field of the Invention

The present invention relates to a method and a apparatus for forming a thin film of an organic electroluminescent device. More particularly, the present invention relates to a method and an apparatus for forming a thin film of an organic electroluminescent device, which enhances the throughput.

2. Description of the Related Art

Organic electroluminescent devices (OEL device) are devices efficiently transferring electricity into photon. In addition, OEL devices have advantages, such as low-operational voltage, high quantum efficiency, wide view angle, simple process, low costs, high-response speed and full color characteristics, adapted to be applied to displays application. Accordingly, OEL devices have been widely used in indicating lamps, displays and optical pick-ups.

Organic electroluminescent devices are devices that use the self-luminescence characteristic of organic functional materials for performing the function of displaying. The type of organic electroluminescent devices includes small molecule organic electroluminescent device (SM-OEL) and polymer electroluminescent device (PEL) according to the molecular weight of the organic functional materials.

An organic electroluminescent device comprises a glass substrate, a metal electrode, an indium-tin oxide (ITO) electrode and an organic electroluminescent layer. The metal electrode serves as a cathode, and the ITO electrode serves as an anode. When a forward bias is applied there-between, electrons and holes are injected into the organic electroluminescent layer from the metal electrode and the ITO layer, respectively. The electrons recombine with the holes to generate photons for luminescence. Following are the descriptions of a conventional method for fabricating the cathode of the organic electroluminescent device.

FIG. 1 is a schematic drawing showing a prior art film-forming apparatus for fabricating a cathode of an organic electroluminescent device. Referring to FIG. 1, the apparatus comprises a loading chamber 210, a plurality of vacuum chamber 220, an unloading chamber 230, a first film-forming apparatus 240a and a second film-forming apparatus 240b. The vacuum chambers 220 comprise a connecting chamber 222, a first film-forming chamber 224 and a second film-forming chamber 226. In addition, the loading chamber 210 and the unloading chamber 230 are connected with the vacuum chambers 220 respectively. The first film-forming chamber 224 and the second film-forming chamber 226 are connected with the connecting chamber 222 respectively. The connecting chamber 222 is further connected with the loading chamber 210 and the unloading chamber 230. Moreover, the first film-forming apparatus 240a is disposed in the first film-forming chamber 224, and the second film-forming apparatus 240b is disposed in the second film-forming chamber 226.

Following are the descriptions of the process flow for forming a cathode of an organic electroluminescent device in the prior art film-forming apparatus. First, a substrate 100 is provided. The substrate 100 has a patterned anode and an organic electroluminescent layer thereon. Additionally, the organic electroluminescent layer is a single-color organic electroluminescent layer.

The substrate 100 is transferred into the first film-forming chamber 224 along the route 250 and through the loading chamber 210, the gate 212, the connecting chamber 222 and the gate 224a. A first conductive layer is formed on the substrate 100 by the first film-forming appratus 224. Then, the substrate 100 is transferred into the second film-forming chamber 226 along the route 250 and through the first film-forming apparatus 224, the gate 224a, the connecting chamber 222 and the gate 226a. A second conductive layer is formed on the substrate 100 by the second film-forming apparatus 240b.

After the formation of the second conductive layer, the substrate 100 is transferred into the unloading chamber 230 along the route 250 and through the second film-forming chamber 226, the gate 226a, the connecting chamber 222 and the gate 222a. Accordingly, the process for forming the cathode of the prior art organic electroluminescent device is finished. As described above, the loading chamber 210 and the unloading chamber 230 are a non-vacuum environment or a vacuum environment, respectively. The connecting chamber 222, the first film-forming chamber 224 and the second film-forming chamber 226 are vacuum environment.

It should be noted that the prior art method has to align the substrate and the mask before forming the first and the second conductive layers. As to the process for forming the two conductive layers, two alignment processes are required. Accordingly, the process time for forming the cathode of the device is increased. In addition, to contain the alignment apparatus, the space of the film-forming chamber should be expanded which means that large vacuum environment is required. Accordingly, the cost of equipment is also raised. Furthermore, when the alignment apparatus does not function normally, the alignment apparatus in the film-forming chamber have to be repaired and the vacuum environment of the film-forming chamber can not be kept. In another aspect, after the alignment apparatus is repaired, the environment of the film-forming chamber has to be recovered as vacuum environment.

### SUMMARY OF INVENTION

Therefore, the present invention is to provide a method for forming a thin film layer of an organic electroluminescent device, which aligns the mask and the substrate under non-vacuum environment, then forms the thin film layer under vacuum environment so as to enhance the throughput of the film-forming apparatus.

The present invention is to provide a film-forming apparatus having an alignment chamber. When the alignment apparatus disposed in the alignment chamber fails, the film-forming apparatus can still form the thin film layer.

The present invention discloses a method for forming a thin film layer of an organic electroluminescent device, which is adapted to form a patterned thin film layer on a substrate. The method comprises: providing a mask; aligning the substrate and the mask under non-vacuum environment, fastening the mask with the substrate; and transferring the fastened substrate and mask into vacuum environment, forming the patterned thin film layer by the mask.

According to the preferred method for forming a thin film layer of an organic electroluminescent device of the present invention, the non-vacuum environment is atmosphere environment or environment having water and/or oxygen concentration about from 0.1 to 100 ppm. In addition, the step of forming the patterned thin film layer is performed, for example, by vapor deposition or sputtering. The step of forming the patterned thin film layer comprises, for example, forming a first conductive layer on the substrate by using the mask; and forming a second conductive on the first conductive layer by using the mask.

To achieve the objects described above, the present invention discloses another method for forming a thin film layer of an organic electroluminescent device, which is adapted to form a patterned thin film layer on a substrate. The method comprises, for example, providing a film-forming apparatus, comprising at least one vacuum chamber and at least one non-vacuum chamber; aligning the substrate and the mask in the non-vacuum chamber, fastening the mask with the substrate; and transferring the fastened substrate and mask into the vacuum chamber, forming the patterned thin film layer by the mask.

According to the preferred method for forming a thin film layer of an organic electroluminescent device of the present invention, the non-vacuum environment is atmosphere environment or environment having water and/or oxygen concentration about from 0.1 to 100 ppm. In addition, the step of forming the patterned thin film layer is performed, for example, by vapor deposition or sputtering. The step of forming the patterned thin film layer comprises, for example, forming a first conductive layer on the substrate by using the mask; and forming a second conductive on the first conductive layer by using the mask.

To achieve the objects described above, the present invention discloses a film-forming apparatus, adapted to form a patterned thin film layer on a substrate by a mask. The apparatus comprises, for example, at least one vacuum chamber, at least one non-vacuum chamber, an alignment apparatus, and a film-forming device. The alignment apparatus is disposed in the non-vacuum chamber and adapted to align the substrate and the mask. The film-forming device is disposed in the vacuum chamber, wherein the film-deposition device forms the patterned thin film layer by using the mask.

According to the preferred film-forming apparatus of the present invention, the apparatus further comprises a transferring apparatus, disposed in the vacuum chamber and the non-vacuum chamber for transferring the substrate therebetween. The non-vacuum environment is atmosphere environment or environment having water and/or oxygen concentration about from 0.1 to 100 ppm. The alignment apparatus comprises, for example, a holder, a first alignment module, a second alignment module and a sensor. The holder is adapted to fix the mask. The first alignment module is adapted to support the holder and to move on an X-Y plane. The second alignment module is disposed over the first alignment module, wherein the second alignment module is adapted to fix the substrate, and the second alignment module is adapted to move along a Z axis. The sensor is disposed over the first alignment module.

According to the preferred film-forming apparatus of the present invention, the first alignment module comprises, for example, a platform and a plurality of fixing devices disposed on the platform. The fixing devices comprise, for example, a wheel type alignment pin or a ball type alignment for the contact surface. The fixing devices further comprise a pushing device, adapted to push the holder for contacting the holder with the wheel type alignment pin or a ball type alignment device. In addition, the fixing devices comprise, for example, a first pushing device and a second pushing device, wherein the first pushing device and the second pushing device are adapted to clamp and fasten the holder on the platform. Additionally, the second alignment module comprises a clamp or a vacuum device. The sensor is, for example, a charge coupled device (CCD).

According to another preferred film-forming apparatus of the present invention, the alignment apparatus comprises, for example, a holder, a first alignment module, a second alignment module and a sensor. The holder is adapted to fix the mask. The first alignment module is adapted to support the holder and the first alignment module is fixed. The second alignment module is disposed over the first alignment module, wherein the second alignment module is adapted to fix the substrate and to move on a X-Y plane and along a Z axis. The sensor is disposed over the first alignment module.

According to the preferred film-forming apparatus of the present invention, the first alignment module comprises, for example, a platform and a plurality of fixing devices disposed on the platform. In addition, the fixing devices comprise, for example, a wheel type alignment pin or a ball type alignment device. The fixing devices further comprise a pushing device, adapted to push the holder for contacting the holder with the wheel type alignment pin or the ball type alignment device. In addition, the fixing devices comprise, for example, a first pushing device and a second pushing device, wherein the first pushing device and the second pushing device are adapted to clamp and fasten the holder on the platform. Additionally, the second alignment module comprises a clamp or a vacuum device. The sensor is, for example, a charge coupled device (CCD).

To achieve the objects described above, the present invention discloses another film-forming apparatus, adapted to form a patterned thin film layer on a substrate by a mask. The apparatus comprises: an alignment chamber, a loading chamber, a plurality of vacuum chambers, an alignment apparatus and a film-forming device. The loading chamber is connected with the alignment chamber. The plurality of vacuum chambers are connected with the loading chamber, comprising, for example, a first film-forming chamber, a second film-forming chamber and a connecting chamber. The connecting chamber connects the loading chamber with the first and the second film-forming chambers. The alignment apparatus is disposed in the alignment chamber and adapted to align the substrate and the mask held by the holder. The film-forming device is disposed in the first and the second film-forming chambers, wherein the film-forming device is adapted to form the patterned thin film layer on the substrate by the mask held by the holder.

According to the preferred film-forming apparatus of the present invention, the apparatus further comprises a transferring apparatus, which is disposed among the alignment chamber, the loading chamber, the connecting chamber, the first film-forming chamber and the second film-forming chamber, for transferring the substrate therebetween. The loading chamber has atmosphere environment, environment having water and/or oxygen concentration about from 0.1 to 100 ppm or vacuum environment. The alignment chamber has atmosphere environment or environment having water and/or oxygen concentration about from 0.1 to 100 ppm.

Accordingly, the present invention aligns the mask held by the holder and the substrate under non-vacuum environment in advance as to enhance the throughput of the process.

In order to make the aforementioned and other objects, features and advantages of the present invention understandable, a preferred embodiment accompanied with figures is described in details below.

### BRIEF DESCRIPTION OF DRAWINGS

FIG. 1 is a schematic drawing showing a prior art film-forming apparatus for fabricating a cathode of an organic electroluminescent device.

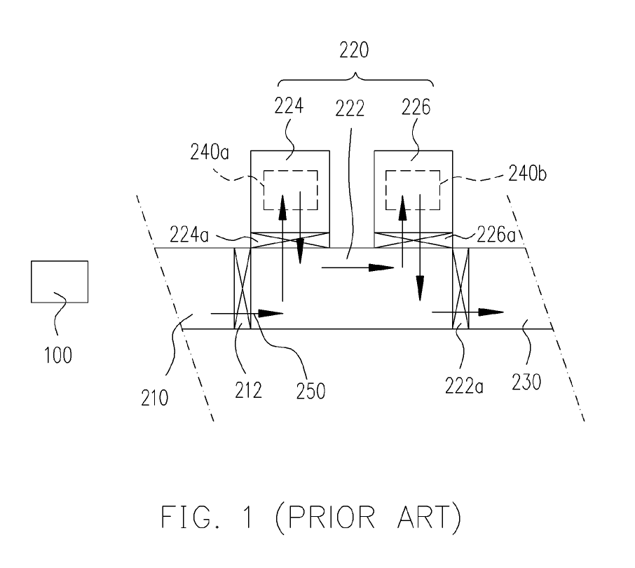

FIG. 2 is a schematic drawing showing a preferred film-forming apparatus of the present invention.

FIG. 3 is a schematic drawing showing a preferred embodiment, wherein the mask is held by the holder.

FIG. 4 is a schematic drawing showing a preferred alignment apparatus of the film-forming apparatus of the present invention.

FIG. 5 is a schematic drawing showing another preferred film-forming apparatus of the present invention.

### DETAILED DESCRIPTION

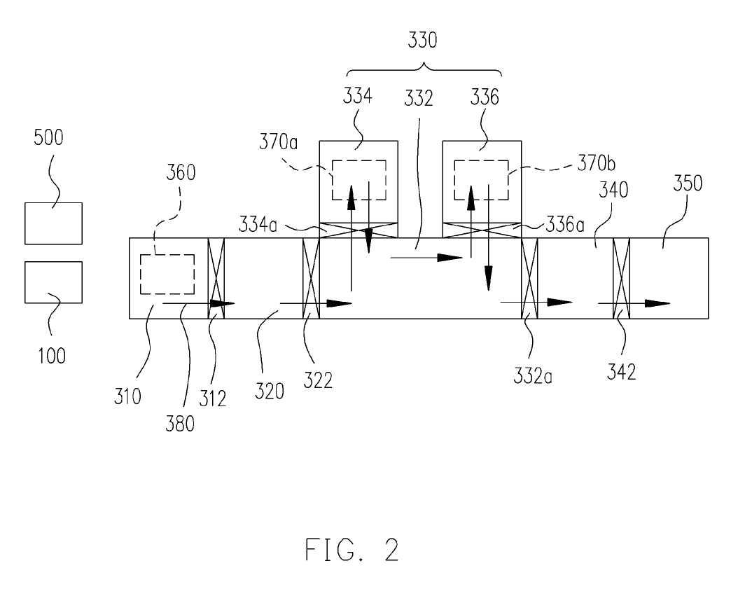

FIG. 2 is a schematic drawing showing a preferred film-forming apparatus of the present invention. Referring to FIG. 2, the film-forming apparatus comprises, for example, an alignment chamber 310, a loading chamber 320, a plurality of vacuum chambers 330, an unloading chamber 340, a separating chamber350, a transferring apparatus (not shown), an alignment apparatus 360, a first film-forming apparatus 370a and a second film-forming apparatus 370b. The loading chamber 320 connects with the alignment chamber 310. The vacuum chambers 330 connect with the loading chamber 320 and the unloading chamber 340. The separating chamber 350 connects with the unloading chamber 340. The film formed by the film-forming apparatus can be, for example, a single layer structure or a multi-layer structure. Each layer can have a thickness, for example, from 5 to 5000 Å or any other thickness range.

Referring to FIG. 2, the vacuum chambers 330 comprise a connecting chamber 332, a first film-forming chamber 334 and a second film-forming chamber 336. The first film-forming chamber 334 and the second film-forming chamber 336 connect with the connecting chamber 332 separately, and connect with the loading chamber 320 and the unloading chamber 340.

Accordingly, the transferring apparatus (not shown) is disposed among the alignment chamber 210, the loading chamber 220, the connecting chamber 230, the first film-forming chamber 240, the second film-forming chamber 250, the separating chamber 270 and the unloading chamber 260 for transferring the substrate 200 therebetween.

Referring to FIG. 2, the first film-forming apparatus 370a is disposed in the first film-forming chamber 334, the second film-forming apparatus 370b is disposed in the second film-forming chamber 336, and the alignment apparatus 360 is disposed in the alignment chamber 310. It should be noted that the loading chamber 320 and the unloading chamber 340 can have, for example, atmosphere environment and vacuum environment, respectively, or environment having water and/or oxygen concentration about from 0.1 to 100 ppm or vacuum environment, respectively. The alignment chamber 310 and the separating chamber 350 can have, for example, environment having water and/or oxygen concentration about from 0.1 to 100 ppm or atmosphere environment, respectively. The environment within the loading chamber 320, the unloading chamber 340, the alignment chamber 310 and the separating chamber 350 vary according to the process. Detail descriptions are described below.

Following are the descriptions of the process flow for forming a thin film of an organic electroluminescent device in the film-forming apparatus above. First, the substrate 100 and the mask 500 are provided. A patterned anode is formed on the substrate 100 and a patterned organic electroluminescent layer is formed thereon. The method of forming the organic electroluminescent layer can be formed by traditional thin film method. Detail descriptions are not repeated.

The substrate 100 and the mask 500 (for example, held by the holder) are transferred into the alignment chamber 310, and are aligned by the alignment apparatus 360 therein. The substrate 100 and the mask 500 are then fastened. To avoid the damage of the organic electroluminescent layer on the substrate 100 causing by moisture or oxygen, nitrogen is filled in the alignment chamber 310 for forming environment having water and/or oxygen concentration about from 0.1 to 100 ppm. The method of fastening the substrate 100 and the mask 500 can be, for example, by a clamping device or the other fixing device.

Then, the fastened substrate 100 and mask 500 is transferred from the alignment chamber 310, along the transferring route 380 and through the gate 312, into the loading chamber 320 by the transferring apparatus (not shown). It should be noted that the loading chamber 320 has, for example, atmosphere environment or environment having water and/or oxygen concentration about from 0.1 to 100 ppm when the substrate 100 and the mask 500 are being transferred therein. In order to perform the subsequent process, the loading chamber 320 is going to be vacuumed.

The gate 322 and the gate 334a are opened. The substrate 100 and the mask 500 are transferred from the loading chamber 320, along the route 380 and through the connecting chamber 332, into the first film-forming chamber 334. In the first film-forming chamber 334, a first film-forming apparatus 370a is disposed therein for forming a first conductive layer, such as Ca.

Then, the gate 334a and the gate 336a are opened. The substrate 100 and the mask 500 are transferred from the first film-forming chamber 334, along the route 380 and through the connecting chamber 332, into the second film-forming chamber 336. In the second film-forming chamber 336, a second film-forming apparatus 370b is disposed therein for forming a second conductive layer, such as Al.

Then, the gate 336a and the gate 332a are opened. The substrate 100 and the mask 500 are transferred from the second film-forming chamber 336, along the route 380 and through the connecting chamber 332, into the unloading chamber 340.

Finally, the gate 340 is opened. The substrate 100 and the mask 500 are transferred from the unloading chamber 340, along the route 380, into the separating chamber 350 in which the substrate 100 and the mask 500 are separated. The separation of the substrate 100 and the mask 500 is performed by a separating apparatus (not shown).

It should be noted that the alignment apparatus is not limited to be disposed in the alignment chamber. It can also be disposed in the other non-vacuum chamber of the film-forming apparatus. Additionally, the alignment apparatus can be disposed outside of the film-forming apparatus, serving the alignment process.

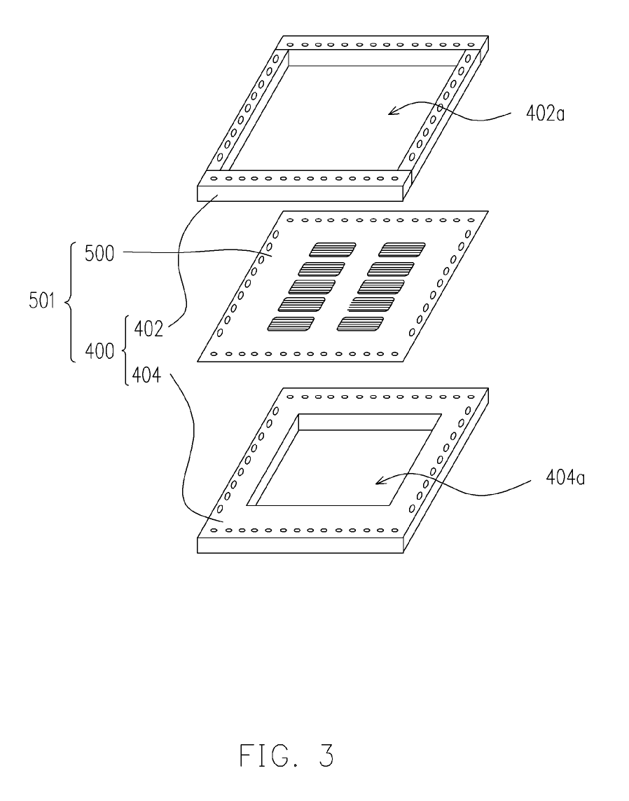

FIG. 3 is a schematic drawing showing a preferred holder of the present invention. Referring to FIG. 3, the holder 400 comprises, for example, a first component 402 and a second component 404. The mask 500 is disposed between the first component 402 and the second component 404, and has alignment marks thereon. In addition, the first component 402 and the second component 404 have openings 402a and 404a, respectively. The openings 402a and 404a expose the surface of the mask 500. After assembling the holder 400 and the mask 500, a mask module 501 constituted by the holder 400 and the mask 500 is obtained.

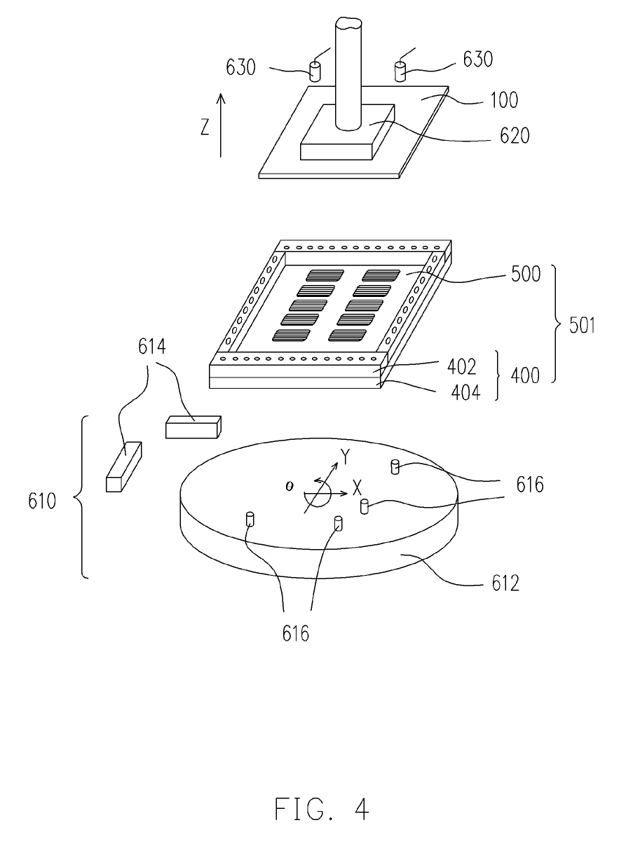

FIG. 4 is a schematic drawing showing a preferred alignment apparatus of the film-forming apparatus of the present invention. Referring to FIG. 4, the alignment apparatus comprises, for example, the holder 400, a first alignment module 610, a second alignment module 620 and a sensor 630. The first alignment module 610 comprises a platform 612 and a plurality of fixing devices, wherein the fixing devices can be, for example, a wheel type alignment pin 616 and a pushing apparatus 614. In addition, the holder 400 is adapted to fix the mask 500. The platform 612 is adapted to support the mask module 501 and to move along X, Y and/or rotate in Z direction.

Referring to FIG. 4, the second alignment module 620 is disposed over the platform 612, and adapted to fix the substrate 100 and to move along Z axis. The second alignment module 620 can be, for example, a clamp or a vacuum device. In addition, the sensor 630 is disposed over the platform 612 and can be, for example, a charge coupled device or the other type sensing device. In the embodiment, the sensor 630 senses whether the marks of the mask 500 align to the marks of the substrate 100. In addition, the pushing apparatus 614 is adapted to push the holder 400 to contact with the wheel type alignment pin 616, wherein the wheel type alignment pin 616 can be, for example, a robot or cylinder device.

Following are the descriptions of the alignment procedure of the substrate 100 and the mask module 501. First, the holder 400 is disposed on the platform 612. The pushing apparatus pushes the holder 400 to contact with the wheel type alignment pin 616. The rough alignment is completed. Then, the second alignment module 620 moves downward along Z axis and towards the holder 400. The sensor 630 is turned on and the platform 612 moves along X and Y axes or rotates along Z axis for accomplishing the fine alignment thereof.

It should be noted that the platform 612 and the second alignment module 620 can move in the other mode. For example, the platform 612 is fixed and the second alignment module 620 is adapted to move along X and Y axes and to rotate along Z axis. In addition, the wheel type alignment pin 616 can be replaced by a ball type alignment device (not shown). In other words, the contact between the fixing devices and the holder 400 can be changed from line contact to point contact for reducing the abrasion and friction therebetween.

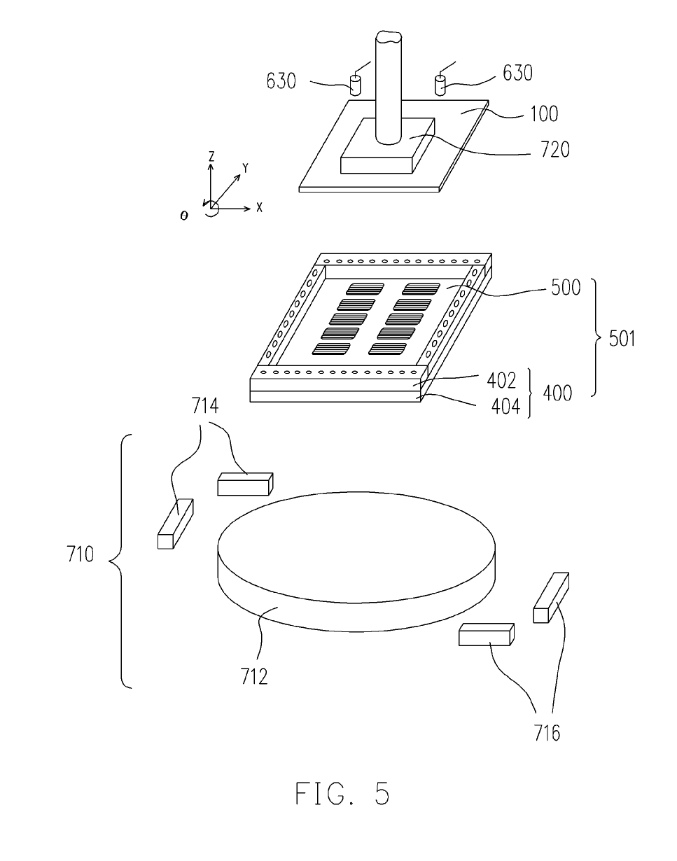

FIG. 5 is a schematic drawing showing another preferred film-forming apparatus of the present invention. Referring to FIG. 5, the alignment apparatus comprises a first alignment module 710, a second alignment module 720 and the sensor 630. The first alignment module 710 comprises a platform 712, a first pushing apparatus 714 and a second pushing apparatus 716. The first pushing apparatus 714 and the second pushing apparatus 716 are adapted to clamp the mask module 501 on the platform 712. In addition, the platform 712 is adapted to support the mask module 501and fixed. The second alignment module 720 is adapted to fix the substrate 100 and to move along X and Y axes and to rotate along Z axis.

It should be noted that the second pushing apparatus 716 is adapted to move mask module 501 to any position on the platform 712, and the first pushing apparatus 714 is adapted to push the mask module 501 to contact with the second pushing apparatus 716. Additionally, when the second pushing apparatus 716 moves to a pre-set position, the push of the first pushing apparatus 714 does not affect the moving of the second pushing apparatus 716. Accordingly, the alignment is finished.

Following are the descriptions of the alignment procedure of the substrate 100 and the mask module 501. First, the second pushing apparatus 716 moves to a pre-set position, and the mask module 501 is disposed on the platform 712. The first pushing apparatus 714 pushes the mask module 501 to contact with the second pushing apparatus 716. The rough alignment is completed. Then, the second the alignment module 720 moves downward along Z axis and towards the holder 400. The sensor 630 is turned on and the second alignment module 720 moves along X axes, Y axes or rotates along Z axis for accomplishing the fine alignment thereof.

In addition, the platform 712 and the second alignment module 720 can move in the other mode. For example, the platform 712 is adapted to move along X and Y axes and to rotate along Z axis and the second alignment module 720 is adapted to move along Z axis.

It should be noted that the method for forming the thin film of the organic electroluminescent device and the film-forming apparatus thereof are not limited to form the cathode of the organic electroluminescent device. The present invention can also be applied to form the organic electroluminescent layer or the other material layer. Detailed descriptions are not repeated.

Accordingly, the method for forming the thin film of the organic electroluminescent device and the film-forming apparatus thereof have following advantages:
1. In the method for forming the thin film of the organic electroluminescent device of the present invention, the mask and the substrate are aligned under non-vacuum environment in advance. Then, the step of forming the thin film layer is performed in the vacuum chamber. The throughput of the film-forming apparatus is, therefore, enhanced.
2. The film-forming apparatus of the present invention has the alignment chamber having the alignment apparatus therein. When the alignment apparatus fails, the film-forming apparatus can still form the thin film layer on the substrate in the film-forming chamber. After the alignment apparatus is recovered, the time to make the environment in the alignment chamber as atmosphere environment or environment having water and/or oxygen concentration about from 0.1 to 100 ppm is less than as vacuum environment.
3. The method for forming the thin film of the organic electroluminescent device and the film-forming apparatus thereof can be used to form the organic electroluminescent layer, the cathode and the other material layer of the organic electroluminescent device.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A method for fabricating a thin film of an organic electroluminescent device, adapted to form a patterned thin film layer on a substrate, the method comprising:
providing a mask;
aligning the substrate and the mask under non-vacuum environment, fastening the mask with the substrate; and transferring the fastened substrate and mask into vacuum environment, forming the patterned thin film layer by the mask.

2. The method for fabricating a thin film of an organic electroluminescent device of claim 1, wherein the non-vacuum environment is atmosphere environment.

3. The method for fabricating a thin film of an organic electroluminescent device claim 1, wherein the non-vacuum environment is environment having water and/or oxygen concentration about from 0.1 to 100 ppm.

4. The method for fabricating a thin film of an organic electroluminescent device of claim 1, wherein the patterned thin film layer is formed by vapor deposition or sputtering.

5. The method for fabricating a thin film of an organic electroluminescent device of claim 1, wherein the step of forming the patterned thin film layer comprises:
forming a first conductive layer on the substrate by using the mask; and
forming a second conductive on the first conductive layer by using the mask.

6. A method for fabricating a thin film of an organic electroluminescent device, adapted to form a patterned thin film layer on a substrate, the method comprising:
providing a film-forming apparatus, comprising at least one vacuum chamber and at least one non-vacuum chamber;
aligning the substrate and the mask in the non-vacuum chamber, fastening the mask with the substrate; and
transferring the fastened substrate and mask into the vacuum chamber, forming the patterned thin film layer by the mask.

7. The method for fabricating a thin film of an organic electroluminescent device of claim 6, wherein the non-vacuum environment is atmosphere environment.

8. The method for fabricating a thin film of an organic electroluminescent device of claim 6, wherein the non-vacuum environment is environment having water and/or oxygen concentration about from 0.1 to 100 ppm.

9. The method for fabricating a thin film of an organic electroluminescent device of claim 6, wherein the patterned thin film layer is formed by vapor deposition or sputtering.

10. The method for fabricating a thin film of an organic electroluminescent device of claim 6, wherein the step of forming the patterned thin film layer comprises:
forming a first conductive layer on the substrate by using the mask; and
forming a second conductive on the first conductive layer by using the mask.

11. A film-forming apparatus, adapted to form a patterned thin film layer on a substrate by a mask, comprising:
at least one vacuum chamber;
at least one non-vacuum chamber;
an alignment apparatus, disposed in the non-vacuum chamber, adapted to align the substrate and the mask; and
a film-forming device, disposed in the vacuum chamber, wherein the film-deposition device forms the patterned thin film layer by using the mask.

12. The film-forming apparatus of claim 11, further comprising a transferring apparatus, disposed in the vacuum chamber and the non-vacuum chamber for transferring the substrate therebetween.

13. The film-forming apparatus of claim 11, wherein the non-vacuum chamber has atmospheres environment.

14. The film-forming apparatus of claim 11, wherein the non-vacuum chamber has water and/or oxygen concentration about from 0.1 to 100 ppm.

15. The film-forming apparatus of claim 11, wherein the alignment apparatus comprises:
a holder, adapted to fix the mask;
a first alignment module, adapted to support the holder, the first alignment module adapted to move on a X-Y plane and/or rotate along along Z axis;
a second alignment module, disposed over the first alignment module, wherein the second alignment module is adapted to fix the substrate, and the second alignment module is adapted to move along a Z axis; and
a sensor, disposed over the first alignment module.

16. The film-forming apparatus of claim 15, wherein the first alignment module comprises:
a platform; and
a plurality of fixing devices, disposed on the platform.

17. The film-forming apparatus of claim 16, wherein the fixing devices comprise a wheel type alignment pin or a ball type alignment device.

18. The film-forming apparatus of claim 17, wherein the fixing devices further comprise a pushing device, adapted to push the holder for contacting the holder with the wheel type alignment pin or a ball type alignment device.

19. The film-forming apparatus of claim 16, wherein the fixing devices comprise:
a first pushing device; and
a second pushing device, wherein the first pushing device and the second pushing device are adapted to clamp and fasten the holder on the platform.

20. The film-forming apparatus of claim 15, wherein the second alignment module comprises a clamp or a vacuum device.

21. The film-forming apparatus of claim 15, wherein the sensor is a charge coupled device.

22. The film-forming apparatus of claim 11, wherein the alignment apparatus comprises:
a holder, adapted to fix the mask;
a first alignment module, adapted to support the holder, the first alignment module is fixed;
a second alignment module, disposed over the first alignment module, wherein the second alignment module is adapted to fix the substrate, and to move on a X-Y plane and along a Z axis and/or rotate along Z axis; and
a sensor, disposed over the first alignment module.

23. The film-forming apparatus of claim 22, wherein the first alignment module comprises:
a platform; and
a plurality of fixing devices, disposed on the platform.

24. The film-forming apparatus of claim 23, wherein the fixing devices comprise a wheel type alignment pin or a ball type alignment device.

25. The film-forming apparatus of claim 24, wherein the fixing devices further comprise a pushing device, adapted to push the holder for contacting the holder with the wheel type alignment pin or the ball type alignment device.

26. The film-forming apparatus of claim 23, wherein the fixing devices comprise:
a first pushing device; and
a second pushing device, wherein the first pushing device and the second pushing device are adapted to clamp and fasten the holder on the platform.

27. The film-forming apparatus of claim 22, wherein the second alignment module comprises a clamp or a vacuum device.

28. The film-forming apparatus of claim 22, wherein the sensor is a charge coupled device.

29. A film-forming apparatus, adapted to form a patterned thin film layer on a substrate by a mask, comprising:
an alignment chamber;
a loading chamber, connected with the alignment chamber;
a plurality of vacuum chambers, connected with the loading chamber, comprising:
a first film-forming chamber;
a second film-forming chamber; and
a connecting chamber, connecting the loading chamber with the first and the second film-forming chambers;
an alignment apparatus, disposed in the alignment chamber, adapted to align the substrate and the mask; and
a film-forming device, disposed in the first and the second film-forming chambers, wherein the film-forming device is adapted to form the patterned thin film layer on the substrate by the mask.

30. The film-forming apparatus of claim 29, further comprising a transferring apparatus, disposed among the alignment chamber, the loading chamber, the connecting chamber, the first film-forming chamber and the second film-forming chamber, for transferring the substrate therebetween.

31. The film-forming apparatus of claim 29, wherein the loading chamber has atmosphere environment, environment having water and/or oxygen concentration about from 0.1 to 100 ppm or vacuum environment.

32. The film-forming apparatus of claim 29, wherein the alignment chamber has atmosphere environment or environment having water and/or oxygen concentration about from 0.1 to 100 ppm.
